(19) United States
(12) Patent Application Publication
(10) Pub. No.: US 2026/0123316 A1
(43) Pub. Date: Apr. 30, 2026

(54) METHOD FOR FORMING SEMICONDUCTOR DEVICE

(71) Applicant: Powerchip Semiconductor Manufacturing Corporation, Hsinchu (TW)

(72) Inventors: Pei-Rong Ni, Hsinchu (TW); Chun-Lin Lu, Hsinchu City (TW)

(73) Assignee: Powerchip Semiconductor Manufacturing Corporation, Hsinchu (TW)

(21) Appl. No.: 19/047,667

(22) Filed: Feb. 7, 2025

(30) Foreign Application Priority Data
Oct. 25, 2024 (TW) 113140765

(51) Int. Cl. H01L 23/00; H01L 21/304; H01L 25/065

(52) U.S. Cl. CPC H10P 52/00; H10W 90/00; H10W 72/019; H10W 72/01951; H10W 80/211; H10W 80/312; H10W 80/327; H10W 90/20; H10W 90/22; H10W 90/792; H10W 90/794; H10W 90/796

(57) ABSTRACT

The present disclosure provides a method for forming a semiconductor device. A first wafer including a first substrate and a first interconnection layer formed on the first substrate is provided. A second wafer including a second substrate and a second interconnection layer formed on the second substrate is provided. The second wafer is stacked on the first wafer. A thinning process is performed on the second substrate of the second wafer. An edge trimming process is performed to remove portions of the second interconnection layer and the second substrate along a perimeter of the second wafer, wherein the edge trimming process results in the first wafer having a recessed surface. A protective layer, surrounding a sidewall of the thinned and edge-trimmed second wafer, is formed on the recessed surface to form a wafer stack structure.

### CROSS-REFERENCE TO RELATED APPLICATION

This application claims the priority benefit of Taiwan application serial no. 113140765, filed on Oct. 25, 2024. The entirety of each of the above-mentioned patent applications is hereby incorporated by reference herein and made a part of this specification.

### BACKGROUND

### Technical Field

The present invention relates to a method of forming a semiconductor device.

### Description of Related Art

With the development of integrated circuits (ICs), the semiconductor industry continues to grow rapidly with the ongoing improvements in the integration density of various electronic components such as transistors, diodes, resistors, or capacitors. These improvements in integration density are mainly directed to the continuous reduction of minimum feature sizes, which allows more components to be integrated into a given region. As the electronic components are developed to have compact size and high performance, in addition to continuously reducing the minimum feature sizes of the electronic components, researchers also continue to improve the techniques for packaging these electronic components to meet current or future needs.

Stacking semiconductor devices has become an effective technique for further reducing the physical sizes of the semiconductor devices. In the stacked semiconductor devices, active circuits such as logic and memory circuits are manufactured on different semiconductor wafers. Two or more semiconductor wafers may be bonded together through suitable bonding techniques to further reduce the overall dimensions of the semiconductor device. However, as the number of the stacked semiconductor wafers gradually increases, defects such as chipping or cracking generated at the edges of the semiconductor wafers during the stacking process will affect the stacked semiconductor devices, making it difficult to meet the current or future requirements.

### SUMMARY

The present invention provides a method of forming a semiconductor device in which a protective layer is formed to surround the sidewall of the thinned and edge-trimmed wafers, so that the defects such as chipping or cracking generated at the edges of the semiconductor wafers during the stacking process can be avoided, and thus the reliability of the semiconductor device can be enhanced.

An embodiment of the present invention provides a method of forming a semiconductor device, which includes the following steps. A first wafer including a first substrate and a first interconnection layer formed on the first substrate is provided. A second wafer including a second substrate and a second interconnection layer formed on the second substrate is provided. The second wafer is stacked on the first wafer. A thinning process is performed on the second substrate of the second wafer. An edge trimming process is performed to remove portions of the second interconnection layer and the second substrate along a periphery of the second wafer, wherein the first wafer is formed to have a recess surface during the edge trimming process. A protective layer surrounding a sidewall of the thinned and edge-trimmed second wafer is formed on the recess surface to form a wafer stacked structure.

In some embodiments, the first interconnection layer and the second interconnection layer are bonded together in a way of hybrid bonding in a step of stacking the second wafer on the first wafer.

In some embodiments, a step of forming the protective layer includes the following steps. A protective material layer covering a rear surface and the sidewall of the thinned and edge-trimmed second wafer is formed on the recess surface of the first wafer. A portion of the protective material layer on the rear surface of the thinned and edge-trimmed second wafer is removed to form the protective layer.

In some embodiments, the protective material layer includes a photo-patternable material.

In some embodiments, a step of removing the portion of the protective material layer on the rear surface of the thinned and edge-trimmed second wafer includes the following steps. Exposure and development processes are performed on the protective material layer to remove the portion of the protective material layer on the rear surface of the thinned and edge-trimmed second wafer.

In some embodiments, the protective material layer is a dry film being photo-patternable, wherein the dry film is laminated on the recess surface of the first wafer and covers the rear surface and the sidewall of the thinned and edge-trimmed second wafer.

Another embodiment of the present invention provides a method of forming a semiconductor device, which includes the following steps. A first wafer stacked structure is formed through the method as described above. A second wafer stacked structure is formed through the method as described above. The second wafer stacked structure is bonded to the first wafer stacked structure, wherein a protective layer of the first wafer stacked structure directly contacts a protective layer of the second wafer stacked structure.

Yet another embodiment of the present invention provides a method of forming a semiconductor device, which includes the following steps. A first wafer including a first substrate and a first interconnection layer formed on the first substrate is provided. An edge trimming process is performed to remove portions of the first interconnection layer and the first substrate along a periphery of the first wafer, so that the first substrate is formed to have a first recess surface. A first protective layer surrounding a sidewall of the edge-trimmed first wafer is formed on the first recess surface to form a first structure. A second wafer including a second substrate and a second interconnection layer formed on the second substrate is provided. An edge trimming process is performed to remove portions of the second interconnection layer and the second substrate along a periphery of the second wafer, so that the second substrate is formed to have a second recess surface. A second protective layer surrounding a sidewall of the edge-trimmed second wafer is formed on the second recess surface to form a second structure. The second structure is bonded to the first structure. A thinning process is performed on the second substrate of the second wafer to form a first wafer stacked structure.

In some embodiments, the first interconnection layer and the second interconnection layer are bonded together in a way of hybrid bonding in a step of bonding the second structure to the first structure, and the first protective layer directly contacts the second protective layer.

In some embodiments, a step of forming the first protective layer includes the following steps. A protective material layer covering a top surface and the sidewall of the edge-trimmed first wafer is formed on the first recess surface of the first substrate. A portion of the protective material layer on the top surface of the edge-trimmed first wafer is removed to form the first protective layer.

In some embodiments, a step of forming the second protective layer includes the following steps. A protective material layer covering a top surface and the sidewall of the edge-trimmed second wafer is formed on the second recess surface of the second wafer. A portion of the protective material layer on the top surface of the edge-trimmed second wafer is removed to form the second protective layer.

In some embodiments, the method of forming the semiconductor device further includes the following steps. A third wafer including a third substrate and a third interconnection layer formed on the third substrate is provided. An edge trimming process is performed to remove portions of the third interconnection layer and the third substrate along a periphery of the third wafer, so that the third substrate is formed to have a third recess surface. A third protective layer surrounding a sidewall of the edge-trimmed third wafer is formed on the third recess surface to form a third structure. The third structure is bonded to the first wafer stacked structure. An edge trimming process is performed on the third structure and the first wafer stacked structure to remove a portion of the third substrate, the third protective layer, the second protective layer, and the first protective layer along a periphery of the third wafer, so that the first recess surface of the first substrate is exposed. A thinning process is performed on the third substrate of the third wafer to form a second wafer stacked structure.

In some embodiments, the method of forming the semiconductor device further includes the following steps. A fourth protective layer is formed on the exposed first recess surface, wherein the fourth protective layer surrounds a sidewall of the second wafer stacked structure.

In some embodiments, the method of forming the semiconductor device further includes the following step. A redistribution layer is formed on the second wafer stacked structure and the fourth protective layer.

In some embodiments, each of the first protective layer, the second protective layer, and the third protective layer includes a photo-patternable material.

Based on the above, in the aforementioned method of forming the semiconductor device, the protective layer is formed to surround the sidewall of the thinned and edge-trimmed wafers, so that the defects such as chipping or cracking generated at the edges of the semiconductor wafers during the stacking process can be avoided, and thus the reliability of the semiconductor device can be enhanced.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1D are schematic cross-sectional views of a method for forming a semiconductor device according to an embodiment of the present invention.

FIG. 2A to FIG. 2K are schematic cross-sectional views of a method for forming a semiconductor device according to another embodiment of the present invention.

FIG. 3 is a schematic top view of FIG. 2J according to an embodiment.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are omitted in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., a wired connection) and a physical disconnection (e.g., a wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

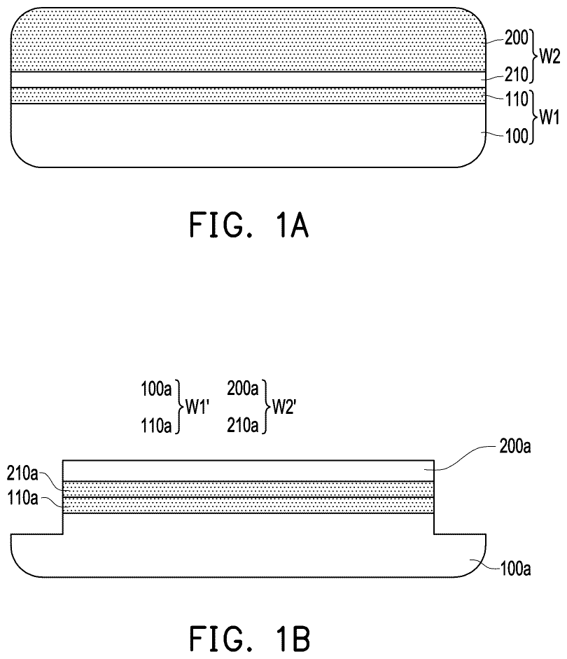

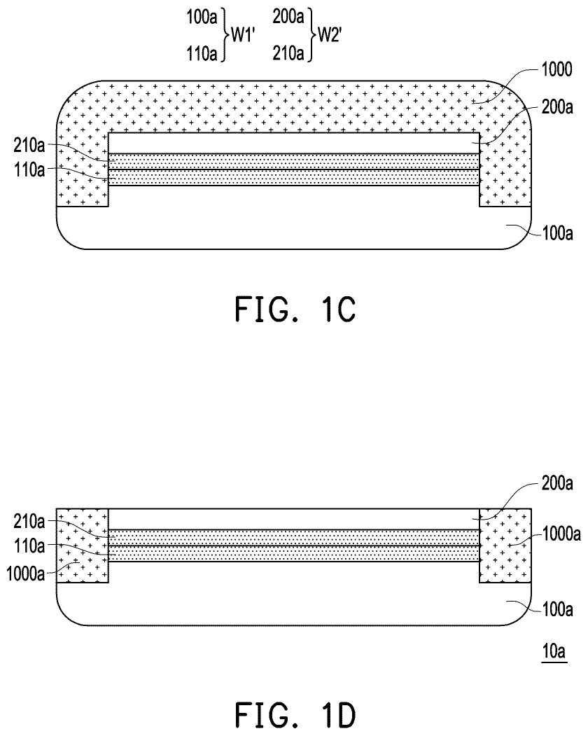

FIG. 1A to FIG. 1D are schematic cross-sectional views of a method for forming a semiconductor device according to an embodiment of the present invention.

First, referring to FIG. 1A, a first wafer W1 is provided. The first wafer W1 includes a first substrate 100 and a first interconnection layer 110 formed on the first substrate 100.

The first substrate 100 may include a semiconductor substrate or a semiconductor-on-insulator (SOI) substrate, or an element layer formed on the semiconductor substrate or the SOI substrate.

The semiconductor materials in the semiconductor substrate or in the SOI substrate may include an element semiconductor, an alloy semiconductor, or a compound semiconductor. For example, the element semiconductor may include Si or Ge. The alloy semiconductor may include SiGe, SiGeC, or the like. The compound semiconductor may include SiC, III-V semiconductor materials, or II-VI semiconductor materials. The III-V semiconductor materials may include GaN, GaP, GaAs, AlN, AIP, AlAs, InN, InP, InAs, GaNP, GaNAs, GaPAs, AlNP, AlNAs, AlPAs, InNP, InNAs, InPAs, GaAINP, GaAINAs, GaAlPAs, GaInNP, GaInNAs, GalnPAs, InAINP, InAINAs, or InAlPAs. The II-VI semiconductor materials may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of a first conductivity type or a dopant of a second conductivity type complementary to the first conductivity type. For example, the first conductivity type may be p-type, whereas the second conductivity type may be n-type.

The element layer may include active elements such as N-type metal-oxide-semiconductor (NMOS), P-type metal-oxide-semiconductor (PMOS), or complementary metal-oxide-semiconductor (CMOS).

The first interconnection layer 110 may include dielectric layers, conductive layers, and conductive vias formed through a back-end-of-line (BEOL) process. The dielectric layers may include oxides, for example, a tetraethyl orthosilicate (TEOS), a borophosphosilicate glass (BPSG), an oxide formed by a high-density plasma (HDP), an undoped silicate glass (USG), a phosphosilicate glass (PSG), an oxide formed by a spin-coating methods such as a spin-on-glass (SOG) method and a spin-on-dielectric (SOD) method, or an oxide formed by a high aspect ratio process (HARP). The conductive layers and/or the conductive vias may include conductive materials such as metals or metal alloys. The metals and the metal alloys may be, for example, Cu, Al, Ti, Ta, W, Pt, Cr, Mo, or alloys thereof.

Then, a second wafer W2 is provided. The second wafer W2 includes a second substrate 200 and a second interconnection layer 210 formed on the second substrate 200.

The second substrate 200 may include a semiconductor substrate or a semiconductor-on-insulator (SOI) substrate, and an element layer formed on the semiconductor substrate or the SOI substrate.

The semiconductor materials in the semiconductor substrate or in the SOI substrate may include an element semiconductor, an alloy semiconductor, or a compound semiconductor. For example, the element semiconductor may include Si or Ge. The alloy semiconductor may include SiGe, SiGeC, or the like. The compound semiconductor may include SiC, III-V semiconductor materials, or II-VI semiconductor materials. The III-V semiconductor materials may include GaN, GaP, GaAs, AlN, AIP, AlAs, InN, InP, InAs, GaNP, GaNAs, GaPAs, AlNP, AlNAs, AlPAs, InNP, InNAs, InPAs, GaAINP, GaAINAs, GaAlPAs, GaInNP, GaInNAs, GaInPAs, InAINP, InAINAs, or InAlPAs. The II-VI semiconductor materials may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of a first conductivity type or a dopant of a second conductivity type complementary to the first conductivity type. For example, the first conductivity type may be p-type, whereas the second conductivity type may be n-type.

The element layer may include active elements such as N-type metal-oxide-semiconductor (NMOS), P-type metal-oxide-semiconductor (PMOS), or complementary metal-oxide-semiconductor (CMOS).

The second interconnection layer 210 may include dielectric layers, conductive layers, and conductive vias formed through a BEOL process. The dielectric layers may include oxides, for example, a tetraethyl orthosilicate (TEOS), a borophosphosilicate glass (BPSG), an oxide formed by a high-density plasma (HDP), an undoped silicate glass (USG), a phosphosilicate glass (PSG), an oxide formed by a spin-coating methods such as a spin-on-glass (SOG) method and a spin-on-dielectric (SOD) method, or an oxide formed by a high aspect ratio process (HARP). The conductive layers and/or the conductive vias may include conductive materials such as metals or metal alloys. The metals and the metal alloys may be, for example, Cu, Al, Ti, Ta, W, Pt, Cr, Mo, or alloys thereof.

Then, the second wafer W2 is stacked on the first wafer W1. In some embodiments, during a step of stacking the second wafer W2 on the first wafer W1, the first interconnection layer 110 and the second interconnection layer 210 may be bonded together through a bonding method such as a hybrid bonding, for example, but is not limited thereto. In some embodiments, the second wafer W2 and the first wafer W1 may be bonded together in a face-to-face manner.

Subsequently, referring to FIG. 1A and FIG. 1B, a thinning process is performed on the second substrate 200 of the second wafer W2 to form the second substrate 200a. In some embodiments, the thinning process may be performed on the second substrate 200 of the second wafer W2 through a process such as a chemical mechanical polishing (CMP) process, a grinding process, an etching process, or a combination thereof.

Afterwards, an edge trimming process is performed to remove portions of the second interconnection layer 210 and the second substrate 200a along a periphery of the second wafer W2, wherein the first wafer W1′ is formed to have a recess surface during the edge trimming process. For example, the edge trimming process removes a portion of the second substrate 200 along the periphery of the second wafer W2 and portions of the second interconnection layer 210, the first interconnection layer 110, and the first substrate 100 under the portion of the second substrate 200, to form the second substrate 200a, the second interconnection layer 210a, the first interconnection layer 110a, and the first substrate 100a having the recess surface. The thickness of the second substrate 200a is less than the thickness of the first substrate 100a. In some embodiments, the edge trimming process is, for example, a process in which a blade is used as a mechanical cutting tool to remove materials along the outer edge of the wafer. In some embodiments, the edge trimming process may improve the uneven surfaces or the sharp corners generated at the edge of the wafer during the above thinning process.

Then, a protective layer (such as the protective layer 1000a shown in FIG. 1D) surrounding the sidewall of the thinned and edge-trimmed second wafer W2′ is formed on the recess surface of the first substrate 100a, so as to form a wafer stacked structure (such as the wafer stacked structure 10a shown in FIG. 1D). As a result, during the subsequent stacking processes of another semiconductor wafer (as shown in FIG. 1E), the protective layer can avoid defects (e.g., the chipping or cracking issues caused by the uneven surfaces or sharp corners generated at the edge of the wafer during the thinning process) occurring at the edge of the semiconductor wafer during the stacking process, and thus the reliability of the semiconductor device can be enhanced.

On the other hand, the protective layer can keep the trimmed distance at the desired value in the edge trimming process, so that the trimmed distance is not increased as the number of the wafer stacked thereon is increased, and therefore the active region or the functional region of the wafer can keep in the desired area. In some embodiments, the active region or the functional region is, for example, a region where the active elements are formed, a region where the circuit structures are formed, a region where the passive elements are formed, or a combination of those regions.

In some embodiments, the protective layer may be formed by the following steps. Firstly, as shown in FIG. 1B and FIG. 1C, a protective material layer 1000 covering the rear surface and the sidewall of the thinned and edge-trimmed second wafer W2′ is formed on the recess surface of the first wafer W1′. Then, as shown in FIG. 1C and FIG. 1D, a portion of the protective material layer 1000 located on the rear surface of the thinned and edge-trimmed second wafer W2′ is removed to form the protective layer 1000a. In some embodiments, the protective layer 1000a may include a photo-patternable material. For example, the photo-patternable material includes benzocyclobutene (BCB). In this embodiment, a portion of the protective material layer 1000 located on the rear surface of the thinned and edge-trimmed second wafer W2′ may be removed by performing exposure and development processes on the protective material layer 1000. In some embodiments, a baking process (e.g., a soft baking process) may be performed on the protective material layer 1000 after the exposure and development processes. In some embodiments, the protective material layer 1000 is a dry film being photo-patternable, wherein the dry film is laminated on the recess surface of the first wafer W1′ and covers the rear surface and the sidewall of the thinned and edge-trimmed second wafer W2′.

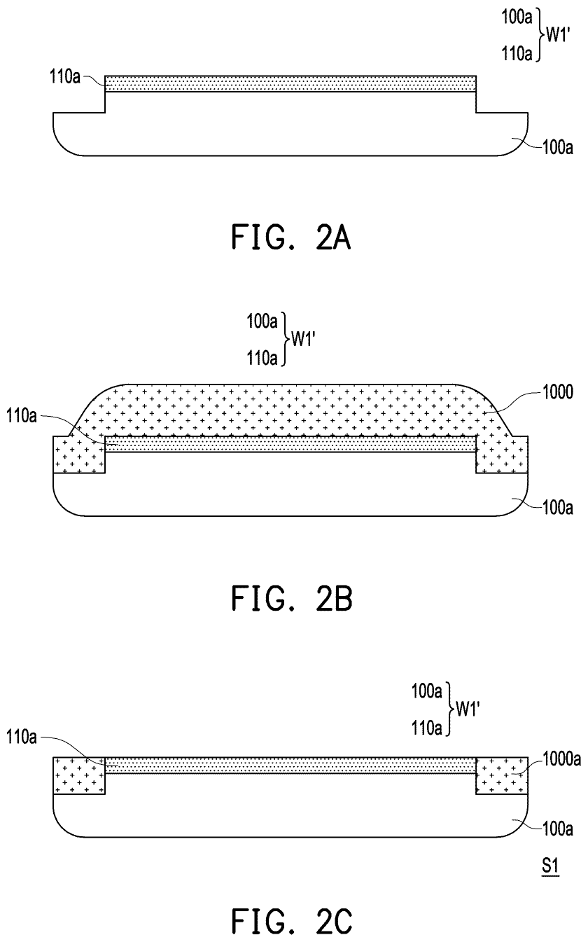

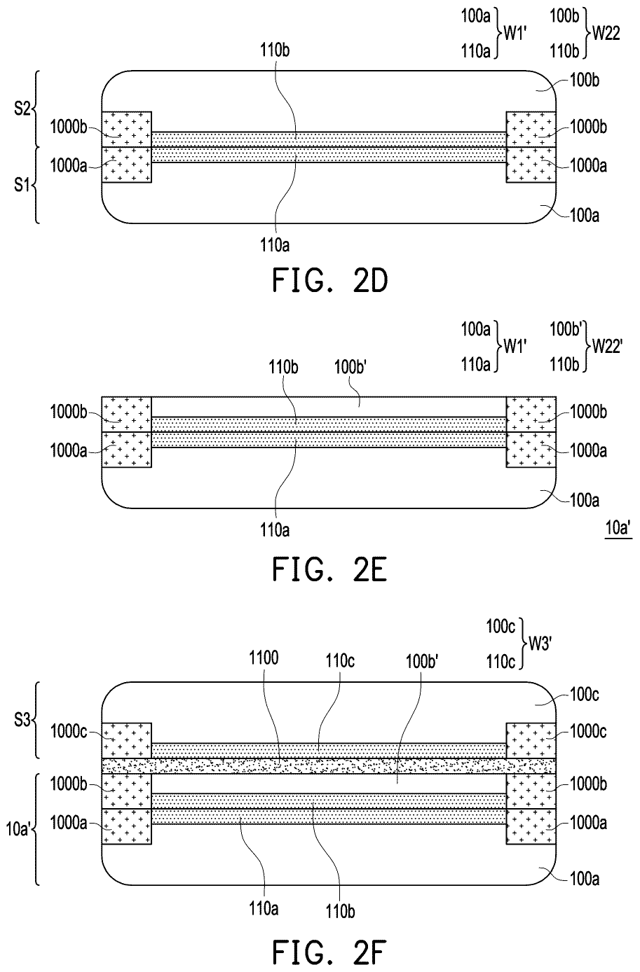

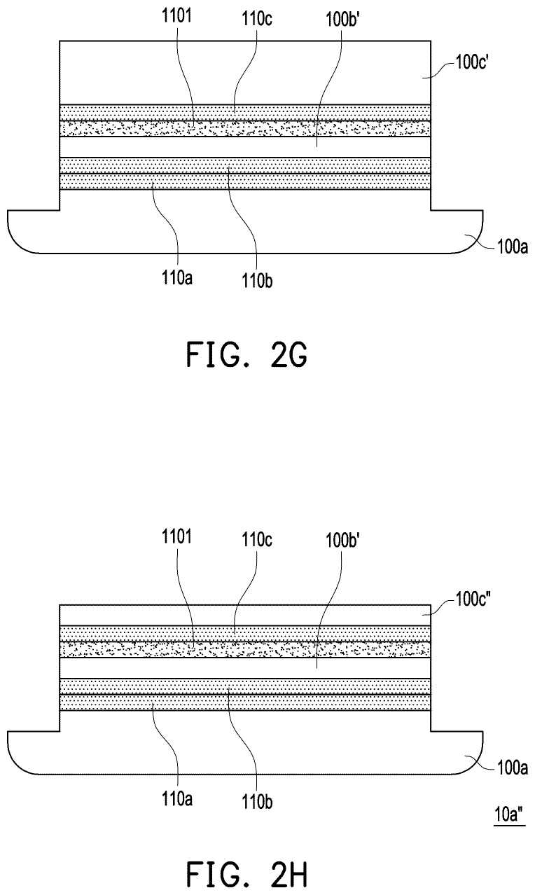

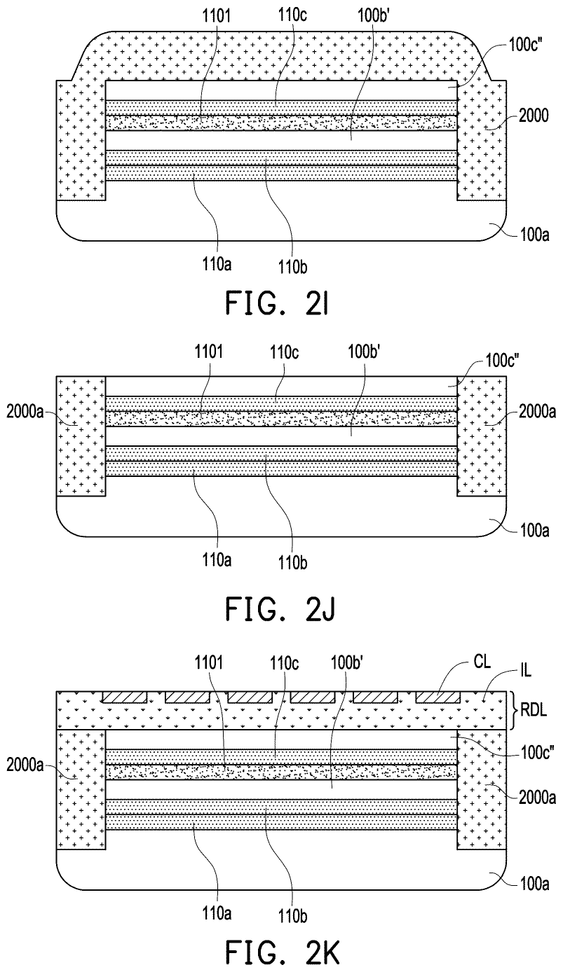

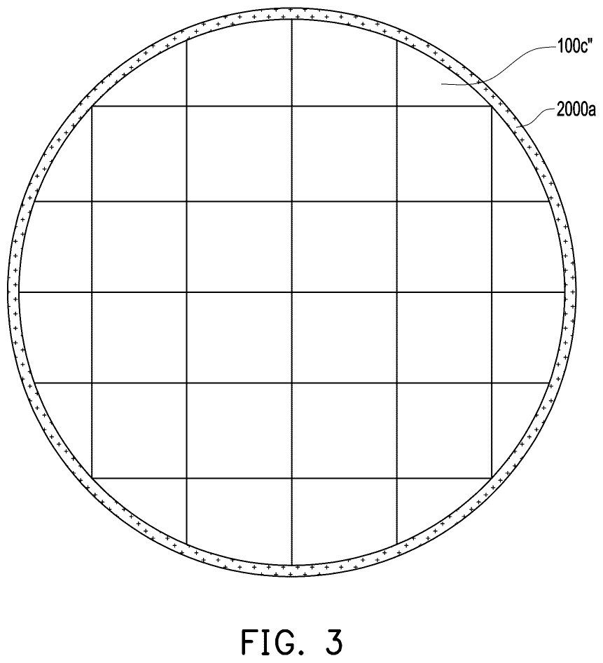

FIG. 2A to FIG. 2K are schematic cross-sectional views of a method for forming a semiconductor device according to another embodiment of the present invention. FIG. 3 is a schematic top view of FIG. 2J according to an embodiment. In FIG. 2A to FIG. 2K, the same or similar components shown in FIG. 1A to FIG. 1E are represented by the same or similar reference numerals, and their materials and manufacturing methods are not repeated hereinafter.

Firstly, referring to both FIG. 1A and FIG. 2A, a first wafer W1 is provided. The first wafer W1 includes a first substrate 100 and a first interconnection layer 110 formed on the first substrate 100. Then, an edge trimming process is performed to remove a portion of the first interconnection layer 110 along the periphery of the first wafer W1 and a portion of the first substrate 100 under the portion of the first interconnection layer 110, such that the first wafer W1′ is formed to include a first substrate 100a having a first recess surface and a first interconnection layer 110a formed on the first substrate 100a.

Then, a first protective layer (e.g., the first protective layer 1000a shown in FIG. 2C) surrounding the sidewall of the edge-trimmed first wafer W1′ is formed on the first recess surface of the first substrate 100a to form a first structure (e.g., the first structure S1 shown in FIG. 2C). In some embodiments, the first protective layer 1000a may be formed by the following steps. Firstly, as shown in FIG. 2B, a protective material layer 1000 covering the top surface and sidewall of the edge-trimmed first wafer W1′ is formed on the first recess surface of the first substrate 100a. Then, as shown in FIG. 2C, a portion of the protective material layer 1000 located on the top surface of the edge-trimmed first wafer W1′ is removed to form the first protective layer 1000a.

Then, referring to FIG. 2D, a second structure S2 is formed by using the steps similar to those steps illustrated in FIG. 2A to FIG. 2C. For example, a second wafer is provided, firstly. The second wafer includes a second substrate and a second interconnection layer formed on the second substrate. Next, an edge trimming process is performed to remove portions of the second interconnection layer and the second substrate along the periphery of the second wafer, such that the second wafer W22 is formed to include a second substrate 100b having a second recess surface and a second interconnection layer 110b formed on the second substrate 100b. Then, a second protective layer 1000b surrounding the sidewall of the edge-trimmed second wafer W22 is formed on the second recess surface of the second substrate 100b to form the second structure S2. In some embodiments, the second protective layer 1000b may be formed through the following steps. Firstly, a protective material layer covering the top surface and sidewall of the edge-trimmed second wafer W22 is formed on the second recess surface of the second wafer W22 by using the similar step as shown in FIG. 2B. Then, a portion of the protective material layer located on the top surface of the edge-trimmed second wafer W22 is removed by using the similar step as shown in FIG. 2C to form the second protective layer 1000b.

Afterwards, as shown in FIG. 2D, the second structure S2 is bonded to the first structure S1. In some embodiments, in the step of bonding the second structure S2 to the first structure S1, the first interconnection layer 110a and the second interconnection layer 110b may be bonded together, for example, in a way of hybrid bonding, but is not limited to, and the first protective layer 1000a directly contacts the second protective layer 1000b.

After that, referring to FIG. 2D and FIG. 2E, a thinning process is performed on the second substrate 100b of the second wafer W22 to form a wafer stacked structure 10a′. In some embodiments, as shown in FIG. 2E, the rear surface of the thinned second substrate 100b′ of the second wafer W22′ may be coplanar with the second protective layer 1000b.

Next, referring to FIG. 2E and FIG. 2F, a redistribution layer 1100 is formed on one side of the thinned second substrate 100b′. The redistribution layer 1100 may include dielectric layers, conductive layers, and conductive vias formed through a BEOL process. The dielectric layers may include oxides, for example, a tetraethyl orthosilicate (TEOS), a borophosphosilicate glass (BPSG), an oxide formed by a high-density plasma (HDP), an undoped silicate glass (USG), a phosphosilicate glass (PSG), an oxide formed by a spin-coating methods such as a spin-on-glass (SOG) method and a spin-on-dielectric (SOD) method, or an oxide formed by a high aspect ratio process (HARP). The conductive layers and/or the conductive vias may include conductive materials such as metals or metal alloys. The metals and the metal alloys may be, for example, Cu, Al, Ti, Ta, W, Pt, Cr, Mo, or alloys thereof.

Next, referring to FIG. 2F, the third structure S3 is formed by using the steps similar to those steps illustrated in FIG. 2A to FIG. 2C. For example, a third wafer is provide, firstly. The third wafer includes a third substrate and a third interconnection layer formed on the third substrate. Then, an edge trimming process is performed to remove portions of the third interconnection layer and the third substrate along the periphery of the third wafer, so that the third wafer W3′ is formed to include a third substrate 100c having a third recess surface and a third interconnection layer 110c formed on the third substrate 100c. Then, a third protective layer 1000c surrounding the sidewall of the edge-trimmed third wafer W3′ is formed on the third recess surface of the third substrate 100c to form the third structure S3. In some embodiments, the third protective layer 1000c may be formed through the following steps. Firstly, in the same or similar manner as shown in FIG. 2B, a protective material layer covering the top surface and sidewall of the edge-trimmed third wafer W3′ is formed on the third recess surface of the third wafer W3′. Then, in the same or similar manner as shown in FIG. 2C, a portion of the protective material layer located on the top surface of the edge-trimmed third wafer W3′ is removed to form the third protective layer 1000c.

Then, referring to FIG. 2F, the third structure S3 is bonded to the wafer stacked structure 10a′. In some embodiments, the third structure S3 may be bonded to the wafer stacked structure 10a′ through a bonding method such as a hybrid bonding, but is not limited thereto.

Thereafter, referring to FIG. 2F and FIG. 2G, an edge trimming process is performed on the third structure S3 and the wafer stacked structure 10a′ to remove a portion of the third substrate 100c and the third protective layer 1000c, the second protective layer 1000b, and the first protective layer 1000a under the portion of the third substrate 100c along the periphery of the third wafer W3′, so that the first recess surface of the first substrate 100a is exposed. In this embodiment, the sidewall of the edge-trimmed third substrate 100c′ is aligned with the sidewall of the second substrate 100b′. In this embodiment, the sidewall of the edge-trimmed redistribution layer 1101 is aligned with the sidewall of the second substrate 100b′. In some embodiments, each of the first protective layer 1000a, the second protective layer 1000b, and the third protective layer 1000c may include a photo-patternable material. In some embodiments, the photo-patternable material may include benzocyclobutene (BCB).

After that, referring to FIG. 2G and FIG. 2H, a thinning process is performed on the third substrate 100c′ of the third wafer to form the wafer stacked structure 10a″. In some embodiments, the thickness of the thinned and edge-trimmed third substrate 100c″ may be approximately equal to the thickness of the second substrate 100b′.

Subsequently, a fourth protective layer (e.g., the fourth protective layer 2000a shown in FIG. 2J and FIG. 3) surrounding the sidewall of the wafer stacked structure 10a″ is formed on the exposed first recess surface of the first substrate 100a. In some embodiments, the fourth protective layer 2000a may be formed by the following steps. Firstly, as shown in FIG. 2H and FIG. 2I, a protective material layer 2000 covering the top surface and sidewall of the edge-trimmed wafer stacked structure 10a″ is formed on the first recess surface of the first substrate 100a. Then, as shown in FIG. 2J, remove a portion of the protective material layer 2000 located on the top surface of the edge-trimmed wafer stacked structure 10a″ to form the fourth protective layer 2000a.

Thereafter, referring to FIG. 2K, a redistribution layer RDL is formed on the wafer stacked structure 10a″ and the fourth protective layer 2000a. In some embodiments, the redistribution layer RDL may include an insulation layer IL and a conductive layer CL formed in the insulation layer IL. The insulation layer IL may include any suitable insulating material such as silicon oxide, silicon nitride, or combinations thereof. The conductive layer CL may include any suitable conductive material such as metal or metal alloy. The metal and the metal alloy may be, for example, Cu, Al, Ti, Ta, W, Pt, Cr, Mo, or an alloy thereof. In some embodiments, the redistribution layer RDL may, for example, redistribute the input/output terminals of the semiconductor chip through the connection structures formed on the semiconductor chip, so that the input/output terminals may be redistributed and configured outside the semiconductor chip.

In summary, in the method of forming the semiconductor device in the above embodiment, the protective layer is formed to surround the sidewall of the thinned and edge-trimmed wafers, so that the defects such as chipping or cracking generated at the edges of the semiconductor wafers during the stacking process can be avoided, and thus the reliability of the semiconductor device can be enhanced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method of forming a semiconductor device, comprising:
providing a first wafer comprising a first substrate and a first interconnection layer formed on the first substrate;
providing a second wafer comprising a second substrate and a second interconnection layer formed on the second substrate;
stacking the second wafer on the first wafer;
performing a thinning process on the second substrate of the second wafer;
performing an edge trimming process to remove portions of the second interconnection layer and the second substrate along a periphery of the second wafer, wherein the first wafer is formed to have a recess surface during the edge trimming process; and
forming a protective layer, on the recess surface, surrounding a sidewall of the thinned and edge-trimmed second wafer to form a wafer stacked structure.

2. The method according to claim 1, wherein the first interconnection layer and the second interconnection layer are bonded together in a way of hybrid bonding in a step of stacking the second wafer on the first wafer.

3. The method according to claim 2, wherein a step of forming the protective layer comprises:
forming a protective material layer, on the recess surface of the first wafer, covering a rear surface and the sidewall of the thinned and edge-trimmed second wafer; and
removing a portion of the protective material layer on the rear surface of the thinned and edge-trimmed second wafer to form the protective layer.

4. The method according to claim 3, wherein the protective material layer comprises a photo-patternable material.

5. The method according to claim 4, wherein a step of removing the portion of the protective material layer on the rear surface of the thinned and edge-trimmed second wafer comprises:
performing exposure and development processes on the protective material layer to remove the portion of the protective material layer on the rear surface of the thinned and edge-trimmed second wafer.

6. The method according to claim 4, wherein the protective material layer is a dry film being photo-patternable, the dry film is laminated on the recess surface of the first wafer and covers the rear surface and the sidewall of the thinned and edge-trimmed second wafer.

7. A method of forming a semiconductor device, comprising:
forming a first wafer stacked structure through the method according to claim 1;
forming a second wafer stacked structure through the method according to claim 1; and
bonding the second wafer stacked structure to the first wafer stacked structure,
wherein a protective layer of the first wafer stacked structure directly contacts a protective layer of the second wafer stacked structure.

8. A method of forming a semiconductor device, comprising:
providing a first wafer comprising a first substrate and a first interconnection layer formed on the first substrate;
performing an edge trimming process to remove portions of the first interconnection layer and the first substrate along a periphery of the first wafer, so that the first substrate is formed to have a first recess surface;
forming a first protective layer surrounding a sidewall of the edge-trimmed first wafer on the first recess surface to form a first structure;
providing a second wafer comprising a second substrate and a second interconnection layer formed on the second substrate;
performing an edge trimming process to remove portions of the second interconnection layer and the second substrate along a periphery of the second wafer, so that the second substrate is formed to have a second recess surface;
forming a second protective layer surrounding a sidewall of the edge-trimmed second wafer on the second recess surface to form a second structure;
bonding the second structure to the first structure; and
performing a thinning process on the second substrate of the second wafer to form a first wafer stacked structure.

9. The method according to claim 8, wherein the first interconnection layer and the second interconnection layer are bonded together in a way of hybrid bonding in a step of bonding the second structure to the first structure, and the first protective layer directly contacts the second protective layer.

10. The method according to claim 9, wherein a step of forming the first protective layer comprises:
forming a protective material layer covering a top surface and the sidewall of the edge-trimmed first wafer on the first recess surface of the first substrate; and
removing a portion of the protective material layer on the top surface of the edge-trimmed first wafer to form the first protective layer.

11. The method according to claim 9, wherein a step of forming the second protective layer comprises:
forming a protective material layer covering a top surface and the sidewall of the edge-trimmed second wafer on the second recess surface of the second wafer; and
removing a portion of the protective material layer on the top surface of the edge-trimmed second wafer to form the second protective layer.

12. The method according to claim 9, further comprising:
providing a third wafer comprising a third substrate and a third interconnection layer formed on the third substrate;
performing an edge trimming process to remove portions of the third interconnection layer and the third substrate along a periphery of the third wafer, so that the third substrate is formed to have a third recess surface;
forming a third protective layer surrounding a sidewall of the edge-trimmed third wafer on the third recess surface to form a third structure;
bonding the third structure to the first wafer stacked structure;
performing an edge trimming process on the third structure and the first wafer stacked structure to remove a portion of the third substrate, the third protective layer, the second protective layer and the first protective layer along the periphery of the third wafer, so that the first recess surface of the first substrate is exposed; and
performing a thinning process on the third substrate of the third wafer to form a second wafer stacked structure.

13. The method according to claim 12, further comprising:
forming a fourth protective layer, on the exposed first recess surface, surrounding a sidewall of the second wafer stacked structure.

14. The method according to claim 13, further comprising:
forming a redistribution layer on the second wafer stacked structure and the fourth protective layer.

15. The method according to claim 12, wherein each of the first protective layer, the second protective layer and the third protective layer comprises a photo-patternable material.
